(19) United States
(12) Patent Application Publication
(10) Pub. No.: US 2021/0408704 A1
(43) Pub. Date: Dec. 30, 2021

(54) MEMORY MODULE AND CONNECTOR FORM FACTOR TO REDUCE CROSSTALK

(71) Applicant: Intel Corporation, Santa Clara, CA (US)

(72) Inventors: Xiang Li, Portland, OR (US); George Vergis, Portland, OR (US); James McCall, Portland, OR (US); Qin Li, Folsom, CA (US)

(21) Appl. No.: 17/470,552

(22) Filed: Sep. 9, 2021

(51) Int. Cl. H01R 12/71; H01R 12/55; H05K 1/18; H01R 13/24

(52) U.S. Cl. CPC H01R 12/714; H01R 12/55; H05K 1/18; H05K 2201/1034; H05K 2201/10159; H05K 2201/10189; H01R 13/24

(57) ABSTRACT

Systems, apparatuses and methods may provide for a memory module that includes a dynamic random access memory (DRAM), a first plurality of contact pads positioned along a first side of the DRAM, a first plurality of L-shaped contacts, wherein each of the first plurality of L-shaped contacts is soldered to one of the first plurality of contact pads, a second plurality of contact pads positioned along a second side of the DRAM, and a second plurality of L-shaped contacts, wherein each of the second plurality of L-shaped contacts is soldered to one of the second plurality of contact pads.

### TECHNICAL FIELD

Embodiments generally relate to memory structures. More particularly, embodiments relate to a memory module and connector form factor that reduces crosstalk.

### BACKGROUND

Double Data Rate 5 (DDR5) dual inline memory module (DIMM) connectors are traditional edge card connectors, with the DIMM being inserted into a connector slot. Edge gold fingers contact spring loaded connector pins to ensure connection. Conventional DDR5 connectors may experience a negative performance impact at relatively high data rates (e.g., beyond 6400 megaTransfers/second (MT/S)) due to the occurrence of more crosstalk between signal contacts. As a result, memory channel bandwidth may be limited.

### BRIEF DESCRIPTION OF THE DRAWINGS

The various advantages of the embodiments will become apparent to one skilled in the art by reading the following specification and appended claims, and by referencing the following drawings, in which:

FIG. 1 is a comparative side sectional view of an example of a conventional memory module and a memory module according to an embodiment;

FIG. 2 is a perspective view of an example of a memory module according to an embodiment; and

FIG. 3 is a side view of an example of a C-shaped contact according to an embodiment.

### DESCRIPTION OF EMBODIMENTS

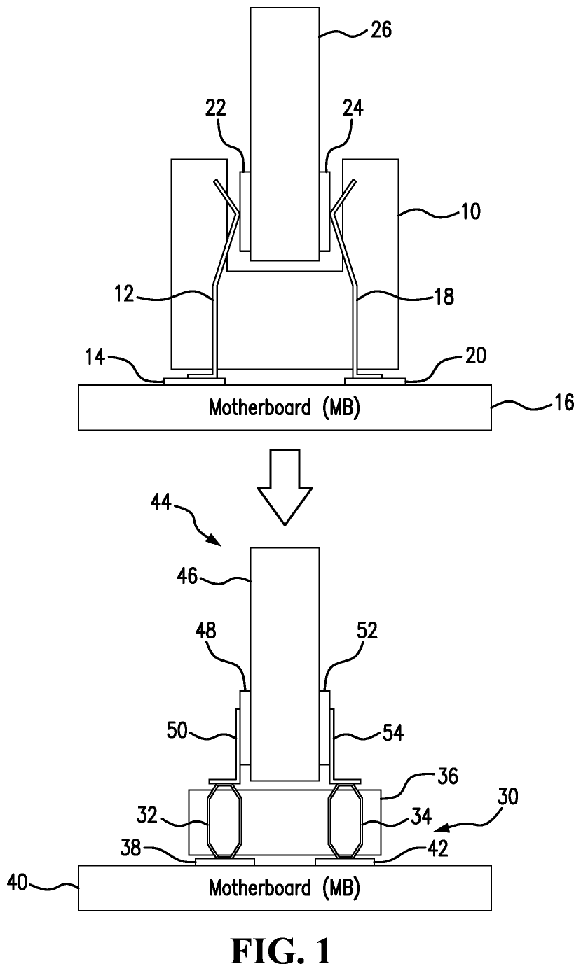

Turning now to FIG. 1, a conventional DDR5 connector 10 is shown in which a first connector pin 12 is soldered to a first surface mount technology (SMT) pad 14 of a motherboard (MB) 16. Similarly, a second connector pin 18 is soldered to a second SMT pad 20 of the motherboard 16. The connector pins 12, 18 make spring loaded contact with respective gold fingers 22, 24 on opposing sides of a DIMM 26. Due to the length of the DDR5 connector 10, current designs may reach a limit on crosstalk reduction.

By contrast, an enhanced connector 30 is generally compressed, with a first O-shaped contact 32 and a second O-shaped contact 34 extending through a housing 36 of the enhanced connector 30. A first (e.g., bottom) portion of the first O-shaped contact 32 is coupled to a first circuit board pad 38 of a motherboard 40 and a first (e.g., bottom) portion of the second O-shaped contact 34 is coupled to a second circuit board pad 42.

A memory module 44 (e.g., DIMM) includes a dynamic random access memory (DRAM, e.g., synchronous DRAM/SDRAM) 46, a first contact pad 48 positioned on a first side of the DRAM 46 and a first L-shaped contact 50, wherein a first (e.g., vertical) portion of the first L-shaped contact 50 is soldered to the first contact pad 48. Additionally, a second (e.g., horizontal) portion of the first L-shaped contact 50 is coupled (e.g., via compression) to a second (e.g., top) portion of the first O-shaped contact 32. The memory module 44 also includes a second contact pad 52 positioned on a second (e.g., opposing) side of the DRAM 46 and a second L-shaped contact 54, wherein a first (e.g., vertical) portion of the first L-shaped contact 54 is soldered to the second contact pad 52. Additionally, a second (e.g., horizontal) portion of the second L-shaped contact 54 is coupled (e.g., via compression) to a second (e.g., top) portion of the second O-shaped contact 34.

The first O-shaped contact 32 is one of a plurality of such contacts extending through the housing 36 along the first side of the DRAM 46. Similarly, the second O-shaped contact 34 is one of a plurality of such contacts extending through the housing 36 along the second side of the DRAM 46. Additionally, the first L-shaped contact 50 is one of a plurality of such contacts positioned along the first side of the DRAM 46 and the second L-shaped contact 54 is one of a plurality of such contacts positioned along the second side of the DRAM 46.

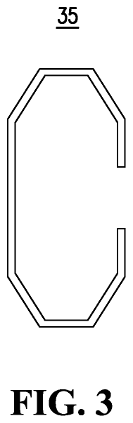

The reduced length (e.g., height) of the O-shaped contacts 32, 34 reduce crosstalk more effectively than the connector pins 12, 18. Accordingly, the enhanced connector 30 enables greater memory channel bandwidth at relatively high data rates. FIG. 3 shows a C-Shaped contact 35 that may be readily substituted for the first O-shaped contact 32 (FIG. 1) and/or the second O-shaped contact 34 (FIG. 1).

The memory module may be part of a memory device that includes non-volatile memory and/or volatile memory. Non-volatile memory is a storage medium that does not require power to maintain the state of data stored by the medium. In one embodiment, the memory structure is a block addressable storage device, such as those based on NAND or NOR technologies. A storage device may also include future generation nonvolatile devices, such as a three-dimensional (3D) crosspoint memory device, or other byte addressable write-in-place nonvolatile memory devices. In one embodiment, the storage device may be or may include memory devices that use silicon-oxide-nitride-oxide-silicon (SONOS) memory, electrically erasable programmable read-only memory (EEPROM), chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thiristor based memory device, or a combination of any of the above, or other memory. The term “storage device” may refer to the die itself and/or to a packaged memory product. In some embodiments, 3D crosspoint memory may comprise a transistor-less stackable cross point architecture in which memory cells sit at the intersection of word lines and bit lines and are individually addressable and in which bit storage is based on a change in bulk resistance. In particular embodiments, a memory module with non-volatile memory may comply with one or more standards promulgated by the Joint Electron Device Engineering Council (JEDEC), such as JESD235, JESD218, JESD219, JESD220-1, JESD223B, JESD223-1, or other suitable standard (the JEDEC standards cited herein are available at jedec.org).

Volatile memory is a storage medium that requires power to maintain the state of data stored by the medium. Examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular embodiments, DRAM of the memory modules complies with a standard promulgated by JEDEC, such as JESD79F for Double Data Rate (DDR) SDRAM, JESD79-2F for DDR2 SDRAM, JESD79-3F for DDR3 SDRAM, or JESD79-4A for DDR4 SDRAM (these standards are available at jedec.org). Such standards (and similar standards) may be referred to as DDR-based standards and communication interfaces of the storage devices that implement such standards may be referred to as DDR-based interfaces.

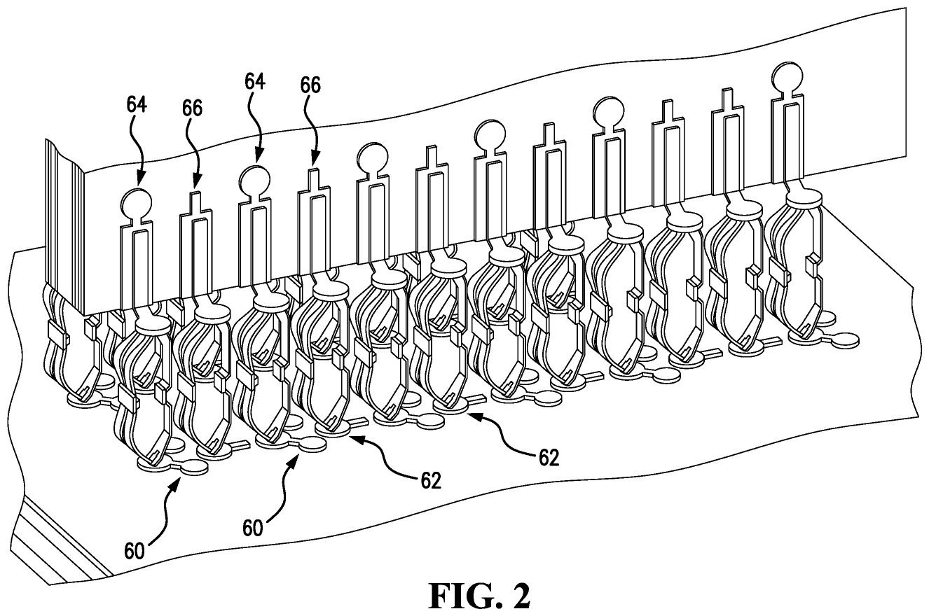

FIG. 2 shows a memory module in which a first plurality of contacts 60 are designated as ground pins and a second plurality of contacts 62 are designated as signal pins. In an embodiment, the first plurality of contacts 60 and the second plurality of contacts 62 are one or more of O-shaped contacts or C-shaped contacts. Similarly, a first plurality of L-shaped contacts 64 are designated as ground pins and a second plurality of L-shaped contacts 66 are designated as signal pins. As a result, the contacts 60, 62 have a signal to ground ratio of 1:1 and the L-shaped contacts 64, 66 have a signal to ground ratio of 1:1. Additionally, the O-shape and/or C-shape geometry of the contacts 60, 62 enables the signal pins to be positioned closer to the ground pins than in the conventional DDR5 connector 10 (FIG. 1). Thus, the illustrated solution enhances performance by further reducing crosstalk.

Indeed, it has been determined that the illustrated solution significantly improves memory channel electrical performance. For example, using a typical memory channel, an eye height at 17.6 Gbps (Giga bits per second) increased from 29 mV (milliVolts) to 72 mV relative to a conventional DDR5 connector and an eye width increased from bps (picoseconds) to 18 ps relative to the conventional DDR5 connector.

### Additional Notes and Examples

Example 1 includes a performance-enhanced computing system comprising a motherboard including a first plurality of circuit board pads and a second plurality of circuit board pads, a connector including a housing, a first plurality of contacts extending through the housing and a second plurality of contacts extending through the housing, wherein a first portion of each of the first plurality of contacts is coupled to one of the first plurality of circuit board pads, wherein a first portion of each of the second plurality of contacts is coupled to one of the second plurality of circuit board pads, and wherein the first plurality of contacts and the second plurality of contacts are one or more of O-shaped contacts or C-shaped contacts, and a memory module including a dynamic random access memory (DRAM), a first plurality of contact pads positioned along a first side of the DRAM, a first plurality of L-shaped contacts, wherein a first portion of each of the first plurality of L-shaped contacts is soldered to one of the first plurality of contact pads and a second portion of each of the first plurality of L-shaped contacts is coupled to a second portion of one of the second plurality of contacts, a second plurality of contact pads positioned along a second side of the DRAM, and a second plurality of L-shaped contacts, and wherein a first portion of each of the second plurality of L-shaped contacts is soldered to one of the second plurality of contact pads and a second portion of each of the second plurality of L-shaped contacts is coupled to a second portion of one of the second plurality of contacts.

Example 2 includes the computing system of Example 1, wherein the first plurality of L-shaped contacts have a signal to ground ratio of 1:1.

Example 3 includes the computing system of Example 1, wherein the second plurality of L-shaped contacts have a signal to ground ratio of 1:1.

Example 4 includes the computing system of Example 1, wherein the memory module is a dual inline memory module.

Example 5 includes the computing system of any one of Examples 1 to 4, wherein the first plurality of contacts have a signal to ground ratio of 1:1.

Example 6 includes the computing system of any one of Examples 1 to 4, wherein the second plurality of contacts have a signal to ground ratio of 1:1.

Example 7 includes a memory module comprising a dynamic random access memory (DRAM), a first plurality of contact pads positioned along a first side of the DRAM, a first plurality of L-shaped contacts, wherein each of the first plurality of L-shaped contacts is soldered to one of the first plurality of contact pads, a second plurality of contact pads positioned along a second side of the DRAM, and a second plurality of L-shaped contacts, wherein each of the second plurality of L-shaped contacts is soldered to one of the second plurality of contact pads.

Example 8 includes the memory module of Example 7, wherein the first plurality of L-shaped contacts and the second plurality of L-shaped contacts have a signal to ground ratio of 1:1.

Example 9 includes the memory module of any one of Examples 7 to 8, wherein the memory module is a dual inline memory module.

Example 10 includes a connector comprising a housing, a first plurality of contacts extending through the housing, and a second plurality of contacts extending through the housing, wherein the first plurality of contacts and the second plurality of contacts are one or more of O-shaped contacts or C-shaped contacts.

Example 11 includes the connector of Example 10, wherein the first plurality of contacts and the second plurality of contacts have a signal to ground ratio of 1:1.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the platform within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A computing system comprising:
a motherboard including a first plurality of circuit board pads and a second plurality of circuit board pads;
a connector including a housing, a first plurality of contacts extending through the housing and a second plurality of contacts extending through the housing, wherein a first portion of each of the first plurality of contacts is coupled to one of the first plurality of circuit board pads, wherein a first portion of each of the second plurality of contacts is coupled to one of the second plurality of circuit board pads, and wherein the first plurality of contacts and the second plurality of contacts are one or more of O-shaped contacts or C-shaped contacts; and
a memory module including a dynamic random access memory (DRAM), a first plurality of contact pads positioned along a first side of the DRAM, a first plurality of L-shaped contacts, wherein a first portion of each of the first plurality of L-shaped contacts is soldered to one of the first plurality of contact pads and a second portion of each of the first plurality of L-shaped contacts is coupled to a second portion of one of the second plurality of contacts, a second plurality of contact pads positioned along a second side of the DRAM, and a second plurality of L-shaped contacts, and wherein a first portion of each of the second plurality of L-shaped contacts is soldered to one of the second plurality of contact pads and a second portion of each of the second plurality of L-shaped contacts is coupled to a second portion of one of the second plurality of contacts.

2. The computing system of claim 1, wherein the first plurality of L-shaped contacts have a signal to ground ratio of 1:1.

3. The computing system of claim 1, wherein the second plurality of L-shaped contacts have a signal to ground ratio of 1:1.

4. The computing system of claim 1, wherein the memory module is a dual inline memory module.

5. The computing system of claim 1, wherein the first plurality of contacts have a signal to ground ratio of 1:1.

6. The computing system of claim 1, wherein the second plurality of contacts have a signal to ground ratio of 1:1.

7. A memory module comprising:
a dynamic random access memory (DRAM);
a first plurality of contact pads positioned along a first side of the DRAM;
a first plurality of L-shaped contacts, wherein each of the first plurality of L-shaped contacts is soldered to one of the first plurality of contact pads;
a second plurality of contact pads positioned along a second side of the DRAM; and
a second plurality of L-shaped contacts, wherein each of the second plurality of L-shaped contacts is soldered to one of the second plurality of contact pads.

8. The memory module of claim 7, wherein the first plurality of L-shaped contacts and the second plurality of L-shaped contacts have a signal to ground ratio of 1:1.

9. The memory module of claim 7, wherein the memory module is a dual inline memory module.

10. A connector comprising:
a housing;
a first plurality of contacts extending through the housing; and
a second plurality of contacts extending through the housing, wherein the first plurality of contacts and the second plurality of contacts are one or more of O-shaped contacts or C-shaped contacts.

11. The connector of claim 10, wherein the first plurality of contacts and the second plurality of contacts have a signal to ground ratio of 1:1.
